(19) United States
(12) Patent Application Publication
(10) Pub. No.: US 2004/0196488 A1
(43) Pub. Date: Oct. 7, 2004

(54) Image forming apparatus, an exchange storage unit and an information administering method

(75) Inventors: Hiroshi Tanaka, Nagano-ken (JP); Keiichi Taguchi, Nagano-ken (JP); Ken Yoshizuka, Nagano-ken (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/776,386

(22) Filed: Feb. 19, 2004

(30) Foreign Application Priority Data
Feb. 27, 2003 (JP) 2003-050604
Apr. 15, 2003 (JP) 2003-110007
Apr. 15, 2003 (JP) 2003-110008

(51) Int. Cl. G06F 15/00; G03F 3/08

(52) U.S. Cl. 358/1.14; 399/24

(57) ABSTRACT

Pieces of administrative information on the used states of the respective units of an engine EG are renewably saved in a RAM 107 provided in an engine controller 10. A CPU 101 administers the life of an apparatus in accordance with these pieces of administrative information. These pieces of administrative information are also saved as auxiliary information in an EEPROM 117 on a main controller 11 mounted on a circuit board separate from the engine controller 10 and suitably updated. The auxiliary information is written in the RAM 107 as new administrative information if necessary. This RAM 107 is provided with an area for saving an exchange flag. This exchange flag is cleared in the RAM 107 mounted in a main body of the apparatus and the administrative information is renewably saved therein on occasion. On the other hand, since the exchange flag is set in a RAM separately prepared as an exchange part, the CPU 101 can understand that information read from this RAM includes no administrative information of the apparatus.

### BACKGROUND OF THE INVENTION

1. Field of the Invention

The invention relates to the administration of consumption articles in an image forming apparatus.

2. Description of the Related Art

In an image forming apparatus of the electrophotographic method, a life of the apparatus needs to be administered to stably form images of good quality. For example, toner as a developing agent is consumed with the use of the apparatus, and the image formation with a small amount of remaining toner in the apparatus results in image deterioration such as density insufficiency and blurred or indistinct images. In order to prevent such image deterioration, the amount of remaining toner in the apparatus has to be constantly precisely grasped. Further, the properties of parts forming the respective units of the apparatus change with time due to, for example, abrasion as the apparatus is used. This results in a variation in the quality of formed images. Thus, it is necessary to grasp the used states of these parts and administer the lives thereof for the repair and exchange at necessary timings.

Thus, in the image forming apparatus of this type, the administration of consumption articles is facilitated by constructing the respective units of the apparatus as function units detachable from a main body and enabling an old function unit to be detached and replaced by a new one if necessary. Further, in order to grasp exchange timings of these function units, administrative information on the used states of the respective units such as cumulative operation hours and working conditions of the respective units is saved in a memory or the like and this information is updated on occasion if necessary.

Many technologies have been proposed thus far for such administration of the consumption articles and the resulting exchange of the function unit, but there have been cases where consumption articles cannot be properly administered only with these technologies. For example, in the case of saving the administrative information in a memory, the administrative information may not be properly written in and read from the memory due to an error in the unit including the memory or a wiring error.

If the administrative information is lost in this way, the lives of the respective function units cannot be properly grasped despite the absence of an abnormality, with the result that the administration of the consumption articles may be hindered and it may become difficult to maintain the image quality.

Further, in the apparatus of this type, the respective function units may be constructed as easily detachable cartridges, so that not only special operators, but also ordinary users can easily exchange the units to thereby reduce an administration cost for the apparatus. To this end, the life administration of the respective units becomes more important and better maintenance is required to enable ordinary users to easily detach and mount the functions units.

### SUMMARY OF THE INVENTION

A main object of the invention is to properly administer consumption articles in an image forming apparatus. Another object thereof is to provide an image forming apparatus in which a unit can be properly and easily exchanged as a consumption article is consumed.

A first aspect of the invention is directed to an image forming apparatus and an information administering method for administering the life of the apparatus in accordance with administrative information on the used state of the apparatus, characterized in that the administrative information is written in a main storage means and, if necessary, written in an auxiliary storage means as auxiliary information, information saved in the main storage means and the auxiliary storage means is read if necessary, and the content of information in the main storage means or the auxiliary storage means is updated based on reading results from the main storage means and the auxiliary storage means.

With the invention having the above construction, since the administrative information on the used state of the apparatus is saved in both the main storage means and the auxiliary storage means, even if one information is lost, it can be compensated for by the other information. By updating these pieces of information on occasion based on the reading results from the main storage means and the auxiliary storage means, the life of the apparatus can be properly administered while the used state of the apparatus is constantly grasped.

A second aspect of the invention is directed to an image forming apparatus in which a main storage means for saving administrative information on the used state of the apparatus is detachably mountable and the life of the apparatus is administered in accordance with the administrative information and an information administering method for such an apparatus, characterized in that the administrative information is read/written from/in the main storage means mounted in the apparatus if necessary, whether or not information read from the main storage means mounted in the apparatus includes identification information representing a difference between this main storage means and the one in which the information was written prior to the readout is judged, and the reading/writing of the administrative information from/in the main storage means is controlled based on a judgment result.

With the invention having the above construction, the administrative information on the used state of the apparatus is read/written from/in the main storage means on occasion, whereby the administrative information is properly updated according to the used state of the apparatus and the life of the apparatus is administered in accordance with the administrative information updated in this way. Here, since the main storage means is detachable, the main storage means in which the administrative information was written before may, for example, be exchanged for another main storage means. Since no administrative information before the exchange is saved in the newly mounted main storage means, information read from the presently mounted main storage means cannot be used to administer the life of the apparatus in such a case. Accordingly, the life of the apparatus can be properly administered by handling the administrative information differently depending on whether the information read from the main storage means includes the identification information representing that this main storage means is not the previously mounted one.

A third aspect of the invention is directed to an image forming apparatus, comprising a photosensitive member cartridge detachably mountable into a main body of the apparatus through a photosensitive member opening formed in the main body of the apparatus; a developing rotary which is rotatably constructed about a center axis thereof with respect to the main body of the apparatus and in which at least one developer cartridge is mountable; a driving means for rotating the developing rotary to position the developing rotary to a specified detachment position where the developing cartridge can be mounted and detached through a developer opening formed in the main body of the apparatus; and a control means for prohibiting the rotation of the developing rotary by the driving means when the photosensitive member cartridge is not mounted in the main body of the apparatus.

With the invention having the above construction, since the developing rotary automatically moves to the detachment position by being rotated by the driving means, user can easily mount and detach the developer cartridge. Further, since the developer cartridge can be mounted and detached only when the developing rotary is positioned to the detachment position, the apparatus can be prevented from damages resulting from improper mounting/detaching operations. In this way, according to the invention, the developer cartridge as a function unit can be easily and properly mounted and detached.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 is a diagram showing a first embodiment of an image forming apparatus according to the invention,

FIG. 2 is a block diagram showing an electrical construction of the image forming apparatus of FIG. 1,

FIG. 3 is a diagram showing a memory map of an FRAM,

FIG. 4 is a flow chart showing a process of updating administrative information,

FIG. 5 is a block diagram showing a second embodiment of the image forming apparatus according to the invention,

FIG. 6 is a perspective view showing the outer configuration of the image forming apparatus of the second embodiment.

FIGS. 7A, 7B and 7C are diagrams showing stop positions of a developer cartridge,

FIG. 8 is a diagram showing a developer operating section of the image forming apparatus,

FIG. 9 is a diagram showing a driving circuit for a developing unit,

FIG. 10 is a flow chart showing a process of judging whether or not to permit a rotation,

FIG. 11 is a table showing judgment results by the flow of FIG. 10,

FIG. 12 is a diagram showing developer information saved in an FRAM, and

FIGS. 13A and 13B are diagrams showing modifications of the image forming apparatus according to the invention.

### DETAILED DESCRIPTION OF THE PREFERRED EMBODIMENTS

(First Preferred Embodiment)

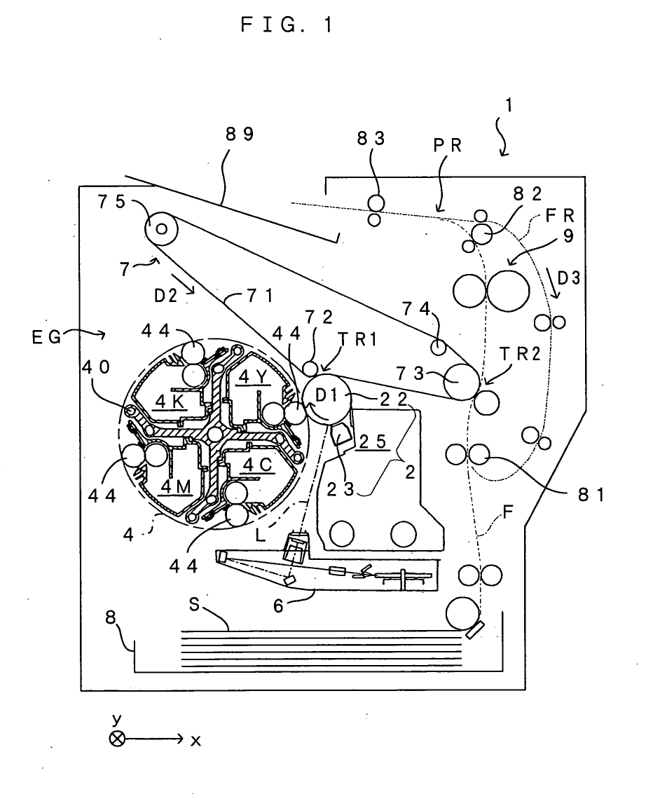

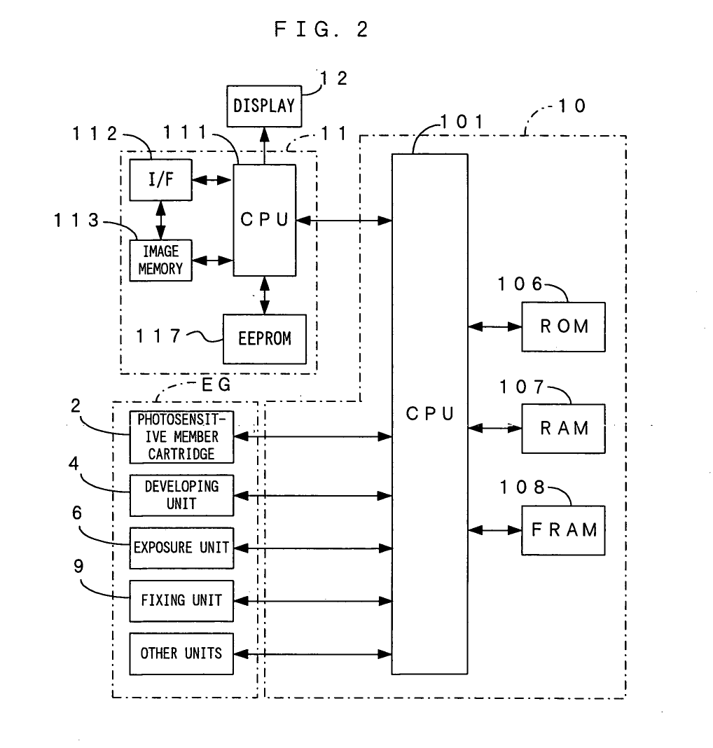

FIG. 1 is a diagram showing a first preferred embodiment of an image forming apparatus according to the invention, and FIG. 2 is a block diagram showing an electrical construction of the image forming apparatus of FIG. 1. This apparatus 1 is an image forming apparatus for forming a full color image by superimposing images of toners (developing agents) of four colors: yellow (Y), cyan (C), magenta (M) and black (K) and forming a monochromatic image using only the black (K) toner. In this image forming apparatus 1, when an image signal is given from an external apparatus such as a host computer to a main controller 11, an engine controller 10 controls the respective units of an engine EG in accordance with a command from the main controller 11 to executes a specified image forming operation, whereby an image corresponding to the image signal is formed on a sheet S.

In this engine EG, a photosensitive member 22 is rotatably provided in a direction of arrow D1 of FIG. 1. Further, a charger unit 23, a rotary developing unit 4 and a cleaning section 25 are arranged around the photosensitive member 22 along its rotating direction D1. A specified charging bias is applied to the charger unit 23 to uniformly charge the outer circumferential surface of the photosensitive member 22 at a specified surface potential. The cleaning section 25 removes the toner residual on the outer surface of the photosensitive member 22 after a primary transfer and collects it in a waste toner tank provided therein. The photosensitive member 22, the charger unit 23 and the cleaning section 25 are incorporated into a photosensitive member cartridge 2, which is detachably mountable into a main body of the apparatus 1 as a single unit.

A light beam L is emitted from an exposure unit 6 toward the outer circumferential surface of the photosensitive member 22 charged by the charger unit 23. The exposure unit 6 exposes the photosensitive member 22 by the light beam L in accordance with the image signal given from the external apparatus to form an electrostatic latent image corresponding to the image signal.

The thus formed electrostatic latent image is developed into a toner image by the rotary developing unit 4. Specifically, the developing unit 4 includes a supporting frame 40 rotatably provided about an axis of rotation normal to the plane of FIG. 1, and a developer for yellow 4Y, a developer for cyan 4C, a developer for magenta 4M and a developer for black 4K containing the toners of the respective colors and constructed as cartridges detachably mountable into the supporting frame 40. The developing unit 4 is controlled by the engine controller 10. The developing unit 4 is rotated in accordance with a control command from the engine controller 10. When the developers 4Y, 4C, 4M, 4K thereof are selectively brought into a specified developing position in contact with the photosensitive member 22 or facing the photosensitive member 22 at a specified gap, the toner is imparted from a developing roller 44 provided in this developer and carrying the toner of the selected color to the outer surface of the photosensitive member 22. In this way, the electrostatic latent image on the photosensitive member 22 is developed in the selected toner color.

The toner image developed in the developing unit 4 as described above undergoes a primary transfer onto an intermediate transfer belt 71 of a transfer unit 7 in a primary transfer region TR1. The transfer unit 7 includes the intermediate transfer belt 71 mounted on a plurality of rollers 72 through 75 and a driving device (not shown) for driving the roller 73 to turn the intermediate transfer belt 71 in a specified turning direction D2. In the case of transferring a color image onto the sheet S, the toner images of the respective colors formed on the photosensitive member 22 are superimposed on the intermediate transfer belt 71 to form the color image, which then undergoes a secondary transfer onto the sheet S dispensed one by one from a cassette 8 and conveyed to a secondary transfer region TR2 along a conveyance path F.

At this time, a timing at which the sheet S is fed to the secondary transfer region TR2 is controlled in order to properly transfer the image on the intermediate transfer belt 71 to a specified position on the sheet S. Specifically, gate rollers 81 are provided before the second transfer region TR2 in the conveyance path F, and the sheet S is fed to the secondary transfer region TR2 at a specified timing by rotating the gate rollers 81 in conformity with a turning timing of the intermediate transfer belt 71.

The sheet S having the color image thus formed thereon is conveyed to be discharged onto a discharge tray 89 provided on the upper surface of the apparatus main body via a fixing unit 9, pre-discharge rollers 82 and discharge rollers 83. Further, in the case of forming images on both surfaces of the sheet S, the rotating directions of the discharging rollers 83 are reversed when the trailing end of the sheet S having the image formed on one surface thereof as described above reaches a reversing position PR behind the pre-discharge rollers 82, whereby the sheet S is conveyed in a direction of arrow D3 along a reversing conveyance path FR. Then, the sheet S enters the conveyance path F again before the gate rollers 81. At this time, the surface of the sheet S to be brought into contact with the intermediate transfer belt 71 in the secondary transfer region TR2 to have an image transferred thereto is the surface opposite from the one where the image was already transferred. In this way, the images can be formed on both surfaces of the sheet S.

The apparatus 1 is also provided with a display 12 controlled by a CPU 111 of the main controller 11 as shown in FIG. 2. This display 12 is adapted to display operation guides to the user, the progress of an image forming operation, and specified messages for notifying an occurrence of an abnormality in the apparatus or a change timing of any unit.

In FIG. 2, identified by 113 is an image memory provided in the main controller 11 for saving an image given from the external apparatus such as a host computer via an interface 112. Identified by 117 is an EEPROM (electrically erasable programmable ROM) for saving data used for the processing in the CPU 111. Identified by 106 is a ROM for saving an arithmetic program to be executed by the CPU 101 and control data used to control the engine EG. Identified by 107 is a RAM for temporarily saving calculation results in the CPU 101 and other data. Identified by 108 is an FRAM (ferroelectric memory) for saving information on the used states of the respective units of the engine EG.

In this embodiment, the main controller 11 and the engine controller 10 are mounted on different printed circuit board modules, which are respectively connected with a motherboard of the apparatus main body via connectors. Accordingly, the respective circuit board modules are individually detachable from the apparatus main body and both correspond to “detachable units” defined in the invention.

As described in detail below, in this embodiment, the FRAM 108 provided in the engine controller 10 and the EEPROM 117 provided in the main controller 11 function as a “main storage means” and an “auxiliary storage means” of the invention, respectively. Further, the FRAM 108 is attached to the engine controller 10 via a socket and serves as a “storage unit” detachable from the apparatus main body.

In this apparatus 1, the information on the used states of the respective units, i.e. the “administrative information” according to the invention is saved in the FRAM 108 and is renewably saved at any time as the used state of the apparatus changes. The CPU 101 administers the lives of the respective units of the apparatus based on this administrative information. For example, a residual amount of the waste toner tank of the cleaning section 25 is renewably saved in the FRAM 108 as a part of the administrative information and, when this residual amount falls to or below a specified value, the CPU 101 notifies it to the CPU 111 of the main controller 11. Upon receiving such a notification, the CPU 111 displays a message urging the exchange of the photosensitive member cartridge 2 on the display 12. A similar message is displayed, for example, when a cumulative value of the working hours of the photosensitive member 22 exceeds a specified value, thereby notifying the user that the life of the photosensitive member cartridge 2 has ended.

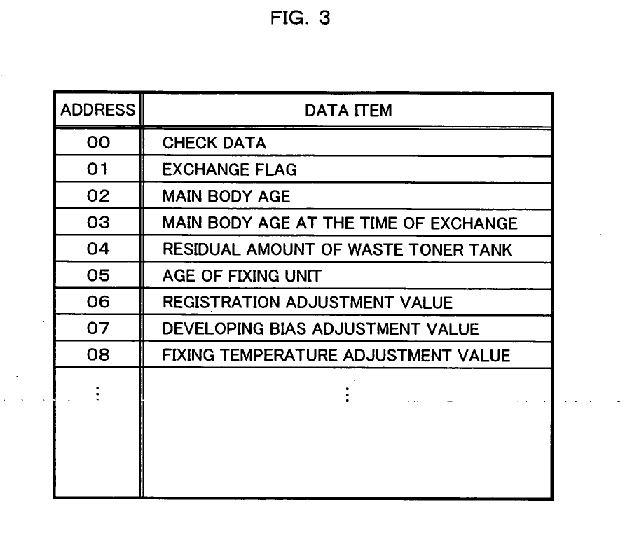

FIG. 3 is a diagram showing a memory map of the FRAM. In this apparatus, various pieces of information corresponding to addresses shown in FIG. 3 are saved as the administrative information in the FRAM 108. Out of these pieces of information, “main body age (address 02)” is an index representing how much the apparatus main body has been used up to the present since it started being used for the first time. For example, a cumulative value of hours during which the apparatus was on or a cumulative value of working hours of the apparatus during which the image forming operation was actually performed may be used as such an index. Specifically, it means that the larger the value of this “main body age”, the more frequently the apparatus has been used, i.e. the larger the working amount of the apparatus. A term “age” is used as an amount representing the working amount of the apparatus up to the present in the following description as well. In short, the older age of the apparatus or a part thereof represents that the apparatus or the part thereof has been more frequently used, i.e. is “old”.

“Main body age at the time of exchange (address 03)” is the main body age when the photosensitive member cartridge 2 was previously exchanged. Specifically, when the photosensitive member cartridge 2 is exchanged by the user, a value of the “main body age” at this time is written at the address 03 as “the main body age at the time of exchange” and saved until the photosensitive member cartridge is exchanged next time. By taking a difference between the “main body age” and the “main body age at the time of exchange” at an arbitrary point of time, how much the presently mounted photosensitive member cartridge 2 has been used up to this point of time can be grasped. In other words, the “main body age” and the “main body age at the time of exchange” are pieces of information representing the working amount of the photosensitive member cartridge 2 up to the present from the point of time when the photosensitive member cartridge 2 was newly mounted.

Besides the above pieces of information, the aforementioned residual amount of the waste toner tank (address 04), the age of the fixing unit 9 (address 05), and further a registration adjustment value (address 06), a developing bias adjustment value (address 07) and a fixing temperature adjustment value (address 08), etc. as parameters concerning process conditions for controlling the image quality are saved in the FRAM 108. It should be noted that the “administrative information” defined in the invention is not limited to these pieces of information, and some of these pieces of information or other pieces of information on the used states of the respective units of the apparatus can be used as the administrative information.

Addresses 00 and 01 are areas for saving a “check data” and an “exchange flag”. These addresses are described in detail later.

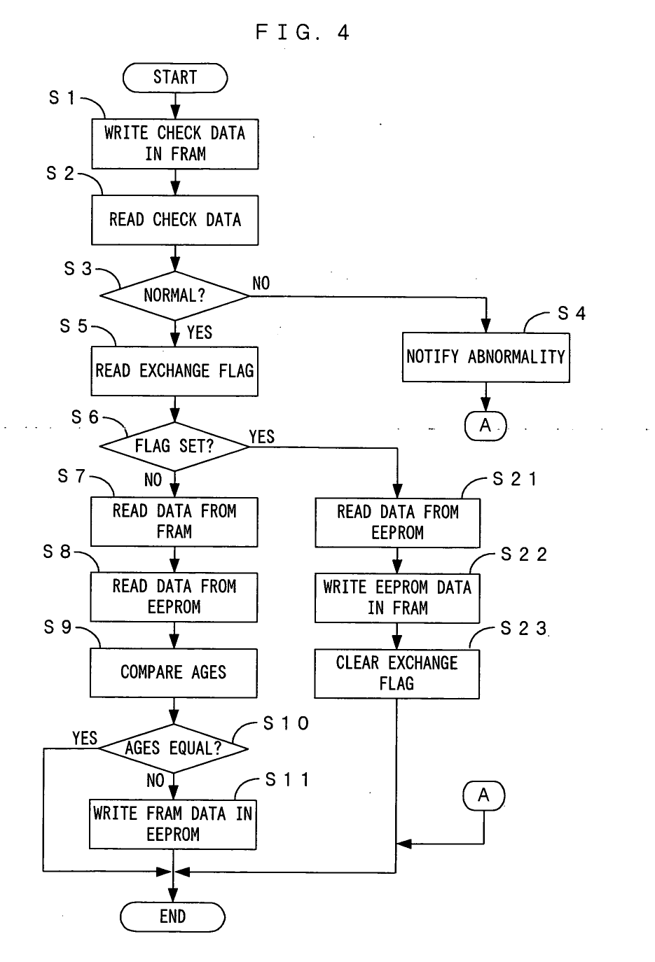

The administrative information saved in the FRAM 108 is written as “auxiliary information” in an empty area (area not used by the CPU 111) of the EEPROM 117 provided in the main controller 11 at a specified timing such as a timing immediately after the apparatus is turned on, at an interval of a specified period, or every time a specified number of image forming operations are performed, which prevents the administrative information from being lost due to a trouble of the FRAM 108 or the like. More specifically, the CPU 101 executes a updating process shown in FIG. 4 if necessary in accordance with a program stored in the ROM 106 beforehand, reads these pieces of information saved in the EEPROM 117 and the FRAM 108 and updates these pieces of administrative information based on the reading result.

The CPU 101 reads and writes the information from and in the EEPROM 117 not directly, but via the CPU 111. In other words, when the CPU 101 reads or writes the information from or in the EEPROM 117, a corresponding request signal is outputted from the CPU 101 to the CPU 111, which in turn accesses the EEPROM 117 and serves to transfer the information between the CPU 101 and the EEPROM 117.

FIG. 4 is a flow chart showing the process of updating the administrative information. In this updating process, the CPU 101 first write a specified check data at the address 00 of the FRAM 108 (Step S1) and then reads this data (Step S2). The check data is for judging whether or not an access of the CPU 101 to the FRAM 108 is normal. The content and bit length of this data can be arbitrarily set, but such a data in which bits “0” and bits “1” are present in a suitably mixed state is preferably used in view of the effectiveness of an operation check. Further, data having a different content may be written every time the operation check is made.

The CPU 101 checks whether or not the written check data and the read data agree with each other and judges whether or not the access to the FRAM 108 is normal (Step S3). Here, unless the two data agree, it represents that either one or both of the writing and the reading were not normally performed. Thus, this flow proceeds to Step S4 in which a signal representing a memory abnormality is sent to the main controller 11 and the updating process is ended. The CPU 111 of the main controller 11 having received this signal causes the display 12 to display a message representing an occurrence of the memory abnormality. Although the display 12 functions as a “notifying means” in this embodiment, the invention is not limited thereto and abnormality may be notified, for example, by blinking a lamp or giving an audible alarm.

The “access abnormality to the FRAM 108” mentioned here does not necessarily means an abnormality of the FRAM 108 itself and may include a state where the FRAM 108 cannot be properly accessed for other reasons such as an abnormal state resulting from an abnormality of a peripheral circuit such as the CPU 101 or a power supply circuit. Accordingly, if this abnormality is detected, not only the above notification is made, but also the repair of a troubled location or the replacement of a troubled part may be made and a succeeding image forming operation may be forbidden until the abnormality is solved. In order to solve this abnormality, the FRAM 108 may be exchanged by being detached from the socket of the circuit board module or may be exchanged together with the circuit board module. Here, it is assumed that a service person detaches the defective FRAM 108 from the socket and mounts a new FRAM which is a separately prepared “exchange storage unit” to solve the abnormality.

On the other hand, if the read data agrees with the written data, the access can be judged to be normal. Subsequently, the exchange flag at address 01 is read (Step S5). Th e exchange flag is set beforehand only in the FRAM prepared as an exchange storage unit in order to distinguish whether the presently mounted FRAM 108 has been mounted in the apparatus or has been newly mounted through the part exchange, and corresponds to “identification information” of the invention. More specifically, if the FRAM 108 is the one that has been mounted from the beginning and saving the information corresponding to the used state of the apparatus, this exchange flag is cleared. On the other hand, if the FRAM 108 is a FRAM stored in a service center or the like as the “exchange storage unit” defined in the invention, this exchange flag is set beforehand.

Of course, the FRAM for exchange having the exchange flag set is different from the one that has been already mounted in the apparatus and has had the administrative information written therein, and no information on the used state of the apparatus is saved therein. In other words, the information read from the FRAM having this flag set does not reflect the present used state of the apparatus and, therefore, cannot be used as the administrative information.

Accordingly, the CPU 101 checks the read exchange flag (Step S6), and the reading and writing from and in the FRAM 108 and EEPROM 117 thereafter are differed based on the checking result. For example, if the flag is set, the FRAM is the one newly mounted by the exchange. Thus, Step S21 follows to read the information saved in the EEPROM 117 as information corresponding to the administrative information. Then, the information read in this way is written at respective address of the FRAM 108 (Step S22). By doing so, the information on the used state of the apparatus before the exchange of the FRAM or at a n update time immediately before the exchange, which information is saved in the EEPROM 117, is written in the FRAM 108. Thus, the CPU 101 can administer the lives of the respective units of the apparatus by taking over the state before the exchange of the FRAM.

After the new administrative information is thus written in the FRAM 108, the exchange flag is cleared and the updating process is ended (Step S23). By doing so, the information saved in the newly mounted FRAM is used as the administrative information similar to the previous FRAM in the succeeding life administration and updating process. Upon a further occasion necessitating the exchange of the storage unit as well, the storage unit having the exchange flag set beforehand may be used as the exchange storage unit.

It should be noted that one bit is sufficient for the exchange flag. Accordingly, bits at address 01 which are not used as the exchange flag can be used to save other pieces of information such as the production lot and the serial number of the FRAM.

On the other hand, If the exchange flag is not set in Step S6, the FRAM is the one that has been mounted and used before. Thus, the process of Step S7 and succeeding Steps is executed on the assumption that the original administrative information is saved. The administrative information saved in the FRAM 108 and the information (auxiliary information) corresponding to the administrative information and saved in the EEPROM 117 are respectively read (Steps S7 and S8), and the ages of the apparatus understood from both pieces of information are compared (Step S9).

This comparison of the ages of the apparatus is described in more detail. As described above, the administrative information saved in the FRAM 108 and the information corresponding to the administrative information and saved in the EEPROM 117 include information (hereinafter, “index information”) representing the “ages” of the apparatus and the respective units thereof. Since these pieces of information are suitably updated, it is represented that the older the information, the younger the “age” understood from the saved index information, and the newer the information, the older the “age”. Accordingly, out of these pieces of information saved in the two memories, the information representing the older age is understood as latest information representing the used state of the apparatus.

Beside this “age”, a cumulative value of the consumed toner amount or the image forming operations can be used as the index information representing the working amount of the apparatus, i.e. how much or how long the apparatus has been used from a certain point of time.

The CPU 101 compares the pieces of information read from the two memories and judges which piece of information is newer, i.e. represents the older age. Here, the administrative information saved in the FRAM 108 is updated frequently on occasion according to the operative state of the apparatus, whereas the information saved in the EEPROM 117 is updated by executing the updating process of FIG. 4. Accordingly, the FRAM 108 cannot have the older information as long as there is no abnormality in the access to the FRAM 108. Thus, the ages of the apparatus understood from both pieces of information are judged to be equal (Step S10). At this time, if there are a plurality of pieces of information representing the age, the ages represented by these pieces of information are assumed to differ if at least one of them represent a different age from the others. However, a judgment may be made based on any one of the pieces of index information.

If both pieces of information represent the equal age of the apparatus, the updating process is immediately ended. If the EEPROM 117 possesses the older information, the information read from the FRAM 108 is written in the EEPROM 117 to update the information to the latest one (Step S11) and then the updating process is ended. In this way, the latest information on the used state of the apparatus is saved in the EEPROM 117.

As described above, in the first preferred embodiment of the present invention, the administrative information on the used state of the apparatus is renewably saved in the FRAM 108. The CPU 101 provided in the engine controller 10 administers the lives of the respective units of the apparatus based on the administrative information. Further, the administrative information is saved on occasion in the EEPROM 117 of the main controller 11 constructed on a circuit board different from the engine controller 10. The pieces of information saved in these memories 108, 117 are read at specified timings and the contents thereof are updated based on the reading result.

Specifically, when the exchange flag is set in the FRAM 108, the CPU 101 writes the information saved in the EEPROM 117 accessed via the CPU 111 in the FRAM 108 as new administrative information. Further, the CPU 101 compares the ages of the apparatus understood from the pieces of information saved in the two memories and updates the older information to the newer information. In this way, the information saved in the EEPROM 117 is suitably updated, and the information reflecting the used state of the apparatus before the exchange is called and used as the administrative information in the case that the FRAM 108 was exchanged due to a defect or the like. Therefore, the life of the apparatus can continue to be properly administered before and after the exchange.

Further, upon an occurrence of an access abnormality to the FRAM 108, it is immediately notified. Thus, the user can take a proper measure against it soon. This can prevent the use r from the continuous use of the apparatus without noticing the abnormality, thereby preventing the used state of the apparatus saved in the EEPROM 117 from being largely deviated from an actual used state. Therefore, the life of the apparatus can be administered while maintaining continuity before and after the exchange of the part.

As described above, in this embodiment, the CPU 111 of the main controller 11 and the CPU 101 of the engine controller 10 function as an “administering means” of the invention together, whereas the FRAM 108 and the EEPROM 117 respectively function as the “main storage means” and the “auxiliary storage means” of the invention. Further, the photosensitive member cartridge 2, the developers 4Y, 4C, 4M, 4K and the circuit board modules having the main controller 11 and the engine controller 10 mounted thereon, which are all detachable from the apparatus main body, correspond to the “detachable units” defined in the invention.

It should be noted that all the pieces of information saved in the FRAM 108 need not be saved in the EEPROM 117 as the auxiliary storage means. It is sufficient to save at least the pieces of information on the life administration of the apparatus in the EEPROM 117. For example, pieces of information to be temporarily saved and resettable in the engine controller 11 such as information on the present process condition, information on the image forming operation being presently performed (distinguishing between color and monochromatic images, the type of sheet) may be deleted from pieces of information to be saved in the EEPROM 117.

(Second Preferred Embodiment)

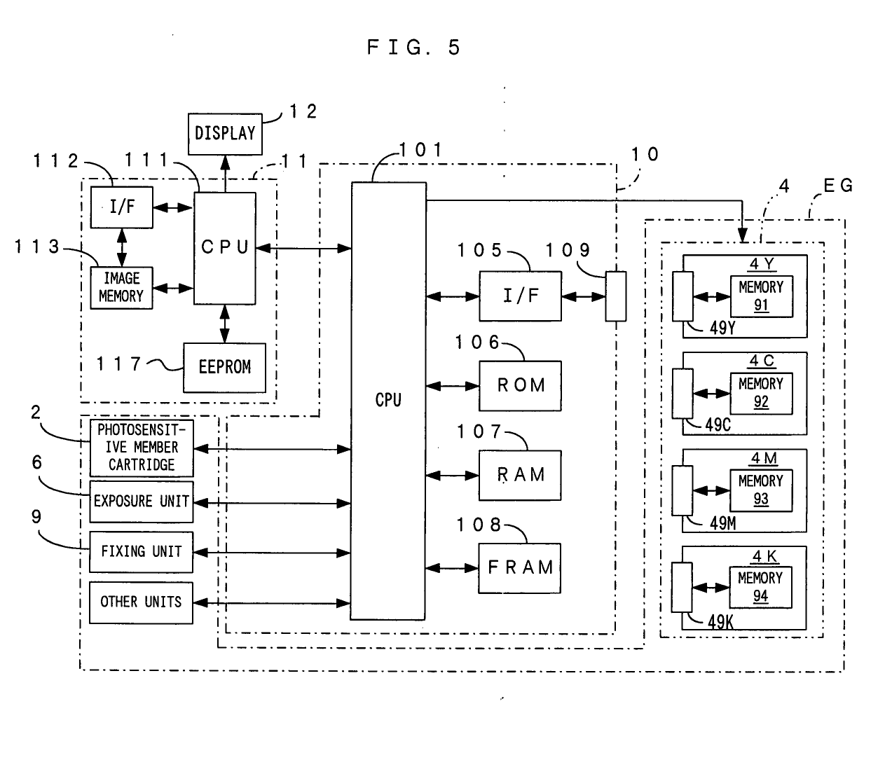

FIG. 5 is a block diagram showing a second preferred embodiment of the image forming apparatus according to the present invention. The principal construction and operation of the image forming apparatus according to the second embodiment are basically same as those of the first embodiment. A large difference between the apparatus of the second embodiment and that of the first embodiment is that nonvolatile memories 91 through 94 are provided for the four developers 4Y, 4C, 4M, 4K, respectively, as shown in FIG. 5. Further, each developer 4Y, 4C, 4M, 4K includes a connector 49Y, 49C, 49M, 49K for the electrical connection of the corresponding memory 91 through 94 with the engine controller 10.

Accordingly, the engine controller 10 is provided with an interface 105 for the communication between these memories and the CPU 101 and a connector 109 movably constructed toward and away from the developing unit 4. When the connector provided in one of the developer comes to be located at such a position as to face the connector 109 of the apparatus main body as the rotary developing unit 4 is rotated, the connector 109 normally located at a position distanced from the developer is moved toward the developer to be connected with the mating connector. Thereby the CPU 101 and the memory provided in this developer can exchange data via the interface 105.

These nonvolatile memories 91 through 94 are adapted to save information on the used states of the respective developers (hereinafter, referred to as “developer information”). Out of physical quantities representing the state and properties of the developer, the one that changes with the use of the developer such as working hours of the developer or a remaining amount of contained toner can be used as this developer information.

In this way, the developers 4Y, 4C, 4M, 4K constructed to be detachable from the apparatus main body are provided with the nonvolatile memories 91 through 94, respectively. The life of the apparatus is administered using the pieces of developer information read from the memories of the developers as a part of the administrative information when the developers are mounted in the apparatus. For example, when the remaining amount of toner in any of the developers falls to or below a specified value, a message urging the exchange of this developer is displayed on the display 12. Upon detaching this developer from the apparatus main body, the information on the used state of this developer, out of the administrative information, is written in the memory prior to the detachment, whereby the life of the developer can be easily and properly administered.

Attention needs to be paid for secure reading and writing of the developer information as the developer is mounted and detached. This is because, even if the above construction is taken, the developer information cannot be read unless the CPU 101 can detect the mounted state of the developer. Further, if the developer is detached without updating the information saved in the memory, the life administration is made based on the wrong information thereafter.

Accordingly, in this embodiment, the developer can be mounted and detached only when the developing unit 4 is positioned at a detachment position to be described later and the developing unit 4 is positioned to the detachment position only under the control of the CPU 101 as described in detail below. Further, the developer can be mounted and detached through a developer opening formed in one side surface of a casing of the apparatus. Since the CPU 101 can securely grasp whether or not the developer is mounted, the above-mentioned problem does not occur.

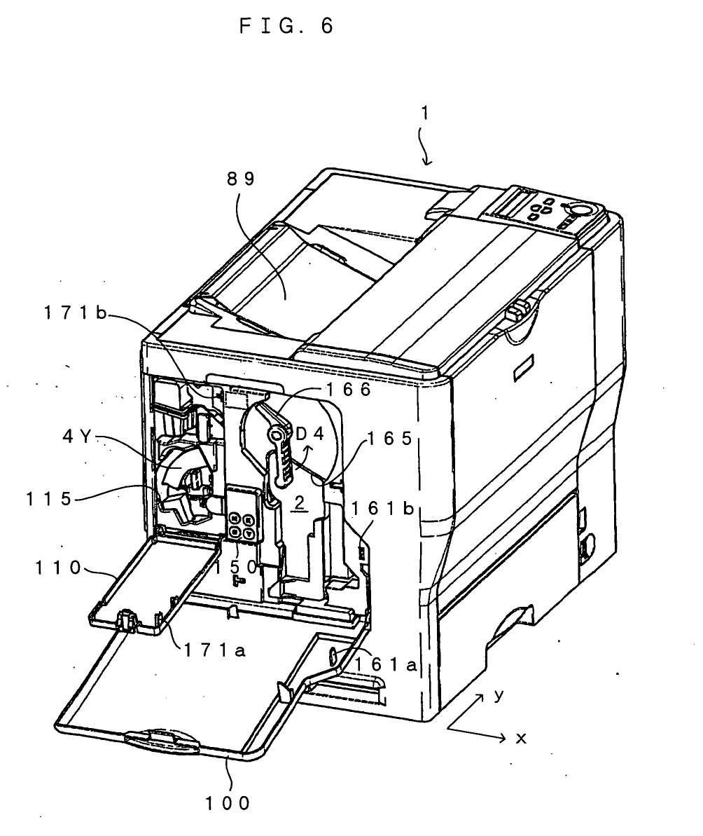

FIG. 6 is a perspective view showing the outer configuration of the image forming apparatus of the second embodiment. As mentioned above, the respective developers 4Y, 4C, 4M, 4K are detachably mountable into the supporting frame 40 and the photosensitive member cartridge 2 is detachably mountable into the apparatus main body in this image forming apparatus 1. As shown in FIG. 6, an outer cover 100 free to open and close is provided at one side surface of the apparatus main body. When the user opens the outer cover 100, a side portion of the photosensitive member cartridge 2 is exposed through a photosensitive member opening 165 formed in the apparatus main body. The photosensitive member cartridge 2 is freed from a locked state by turning a locking lever 166 for fixing the photosensitive member cartridge 2 in a direction of arrow D4, whereby the photosensitive member cartridge 2 can be withdrawn along (−y)-axis direction of FIG. 6. Further, a new photosensitive member cartridge 2 can be mounted by being inserted through the photosensitive member opening 165 along y-axis direction of FIG. 6. Then, the photosensitive member cartridge 2 is fixed by the locking lever 166. When the photosensitive member cartridge 2 is mounted in this way, the photosensitive member opening 165 is substantially closed by the side portion of the photosensitive member cartridge 2.

The apparatus main body is also formed with a developer opening 115 through which the developer cartridge is mounted and detached. An inner cover 110 free to open and close is so provided as to close this developer opening 115. This inner cover 110 is provided at the inner side of the outer cover 100. In other words, the inner cover 110 cannot be opened with the outer cover 100 left closed since the outer cover 100 is formed to cover the developer opening 115 as well. Conversely, the outer cover 100 cannot be closed unless the inner cover 110 is closed. If the developing unit 4 is standing at the detachment position when the user opens this inner cover 110, one of the mounted developers can be detached through the developer opening 115. Similarly, one developer can be mounted through the developer opening 115.

As described above, in this embodiment, the inner cover 110 corresponds to a “developer covering member” of the invention and the outer cover 100 corresponds to a “photosensitive member covering member” of the invention. Further, the outer cover 100 as the “photosensitive member covering member” is formed to cover both the developer opening 115 and the photosensitive member opening 165 in its closed state.

The outer cover 100 is provided with a projection 161a, whereas a hole 161b is formed at a position of the apparatus main body corresponding to this projection 161a. Further, a limit switch 135 to be described later is mounted at the bottom of the hole 161b. When the outer cover 100 is closed, the projection 161a is introduced into the hole 161b formed in the apparatus main body to push the limit switch 135 provided at the bottom of the hole 161b, thereby closing a contact of the limit switch 135.

The inner cover 110 is also provided with a mechanism similar to the above. Specifically, a projection 171a is provided on the inner cover 110, whereas a hole 171b is formed at a corresponding position of the apparatus main body. When the inner cover 110 is closed, the projection 171a is introduced into the hole 171b to push a limit switch 132 (to be described later) provided at the bottom of the hole 171b, thereby closing a contact of the limit switch 132.

Further, a limit switch 133 to be described later is provided at the back side of the photosensitive member opening 165, and a contact thereof is closed when the photosensitive member cartridge 2 is mounted into the apparatus main body. The limit switch 133 is desirably so installed as to close its contact with the photosensitive member cartridge 2 properly mounted in the apparatus main body while not closing its contact in an incompletely mounted state of the photosensitive member cartridge 2. This is because it is necessary to securely detect that the photosensitive member cartridge 2 is mounted lest the developing unit 4 should be rotate in the incompletely mounted state of the photosensitive member cartridge 2 to damage the apparatus.

As described above, in the image forming apparatus of the second preferred embodiment of the present invention, whether the outer cover 100 and the inner cover 110 are open or closed and whether or not the photosensitive member cartridge 2 is mounted can be detected from the contact states of the respective limit switches. The image forming operation is performed only with the outer cover 100 and the inner cover 110 closed and with the photosensitive member cartridge 2 mounted.

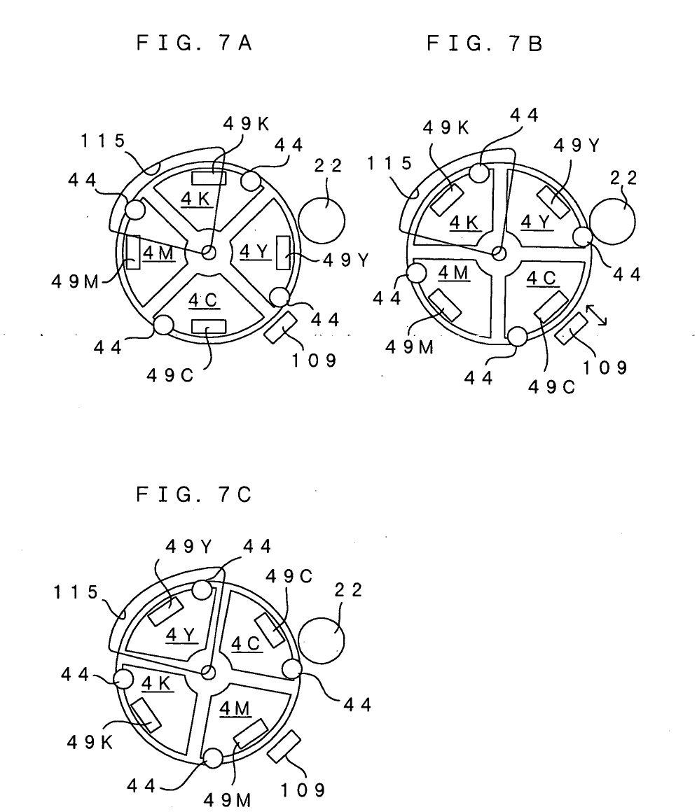

FIGS. 7A, 7B and 7C are diagrams showing stop positions of the developer cartridge. In this image forming apparatus, the developing unit 4 can be positioned and fixed at three kinds of positions shown in FIGS. 7A, 7B and 7C by the engine controller 10 and an unillustrated rotary locking mechanism. These three positions are: (a) home position (FIG. 7A); (b) developing position (FIG. 7B); and (c) detachment position (FIG. 7C). The home position (a) is a position to which the developing unit 4 is positioned when the apparatus is in a standby state where no image forming operation is performed. As shown in FIG. 7A, all the developing rollers 44 provided in the respective developers 4Y, 4C, 4M, 4K are distanced from the photosensitive member 22 and none of the developers 4Y, 4C, 4M, 4K can be detached through the developer opening 115 formed in the apparatus main body.

The developing position (b) is a position to which the developing unit 4 is positioned when an electrostatic latent image on the photosensitive member 22 is developed in a selected toner color. As shown in FIG. 7B, the developing roller 44 provided in one developer (developer 4Y for yellow in the shown example) is so located as to face the photosensitive member 22, and the electrostatic latent image is developed by toner by applying a specified developing bias to the developing roller 44. At this developing position as well, none of the developers can be detached through the developer opening 115. If the outer cover 100 is opened during the image forming operation, the image forming operation is immediately stopped and the developing unit 4 stops after being moved to the home position.

The detachment position (c) is a position taken only upon mounting and detaching the developer. When the developing unit 4 is positioned to this detachment position, one developer appears in the developer opening 115 and can be detached through the developer opening 115 as shown in FIG. 7C. FIG. 7C shows a state where the developer 4Y for yellow appears in the developer opening 115. Further, a new developer can be mounted into the supporting frame 40 carrying no developer. At this detachment position, the developing rollers 44 of all the developers are distanced from the photosensitive member 22. In this way, only one developer appearing in the developer opening 115 can be detached when the developing unit 4 is positioned at the detachment position. Thus, there is no possibility that the user inadvertently mounts or detaches the developer to damage the apparatus.

Since the developing position and the detachment position mentioned above are set for each of the four developers 4Y, 4C, 4M, 4K in this image forming apparatus, there are nine stop positions of the developing unit 4 including one home position.

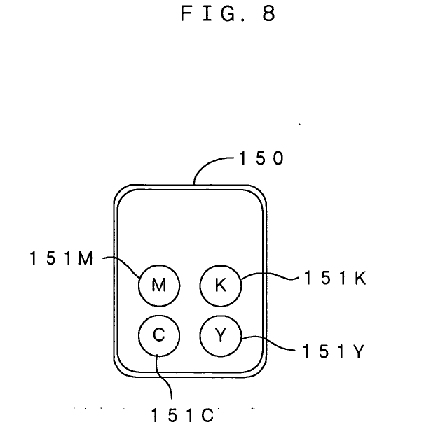

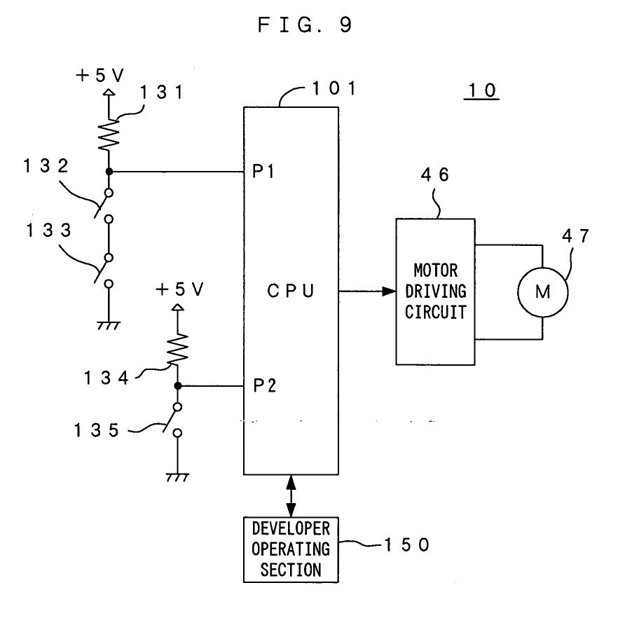

An operation of mounting and detaching the developer in this image forming apparatus is described in more detail with reference to FIGS. 8 and 9. FIG. 8 is a diagram showing a developer operating section of the image forming apparatus, and FIG. 9 is a diagram showing a driving circuit of the developing unit. In this image forming apparatus, the developing unit 4 is positioned to the home position in the standby state where no image forming operation is performed. Further, the developing unit 4 stops after being moved to the home position when the outer cover 100 is opened during the image forming operation. Thus, even if the user opens the outer cover 100 and then opens the inner cover 110 to expose the developer opening 115, the developer cannot be detached immediately.

In this image forming apparatus, the user operates the developer operating section 150 shown in FIG. 8 to move the rotary developing unit 4 to the detachment position, thereby enabling the detachment of the developer. Specifically, when the user presses one of developer operating buttons 151M, 151K, 151C, and 151Y provided at the developer operating section 150 corresponding to a toner color desired to be exchanged, the developing unit 4 is rotated by a specified amount by the driving circuit provided in the engine controller 10 and shown in FIG. 9 to be positioned at the detachment position. In this way, the developer corresponding to the selected toner color appears in the developer opening 115.

The CPU 101 provided in the engine controller 10 also functions as a “control means” of the invention, and output signals from the aforementioned limit switches 132, 133, 135 are inputted thereto as shown in FIG. 9. More specifically, out of the three limit switches, the limit switch 132 for detecting the open and closed states of the inner cover 110 and the limit switch 133 for detecting the mounted state of the photosensitive member cartridge 2 are connected in series and connected with the other end of a pull-up resistor 131 having one end thereof connected with a power source. On the other hand, the limit switch 135 for detecting the open and closed states of the outer cover 100 is connected with the other end of a pull-up resistor 134 having one end thereof connected with the power source. The other ends of the respective pull-up resistors 131, 134 are connected with input ports P1, P2 of the CPU 11.

Thus, the CPU 101 can discriminate the states of the inner cover 110, the outer cover 100 and the photosensitive member cartridge 2 based on levels of voltages inputted to the two input ports P1, P2. Specifically, the following discriminations can be made:

(1) H-level at the port P1: The inner cover 110 is open or the photosensitive member cartridge 2 is not mounted.

(2) L-level at the port P1: The inner cover 110 is closed and the photosensitive member cartridge 2 is mounted.

(3) H-level at the port P2: The outer cover 100 is open.

(4) L-level at the port P2: The outer cover 100 is closed.

Based on the discrimination result, the CPU 101 judges whether or not to permit the rotation of the developing unit 4 as follows.

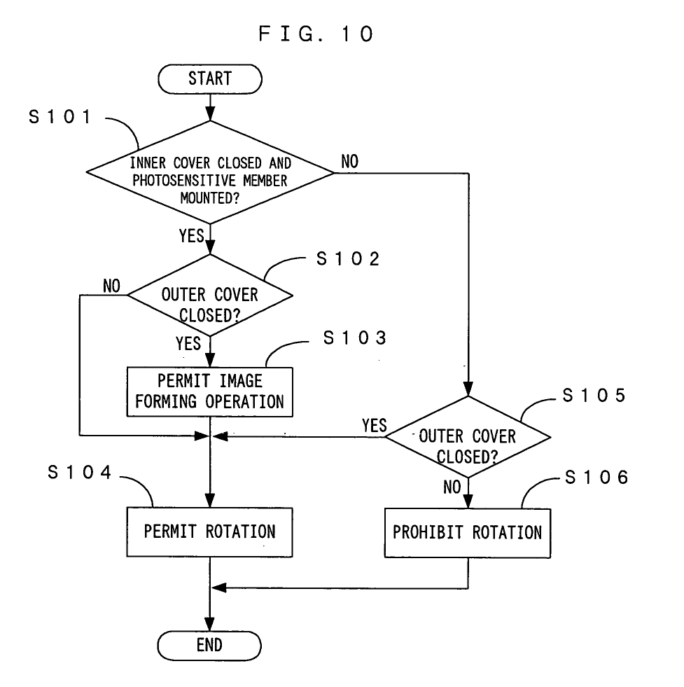

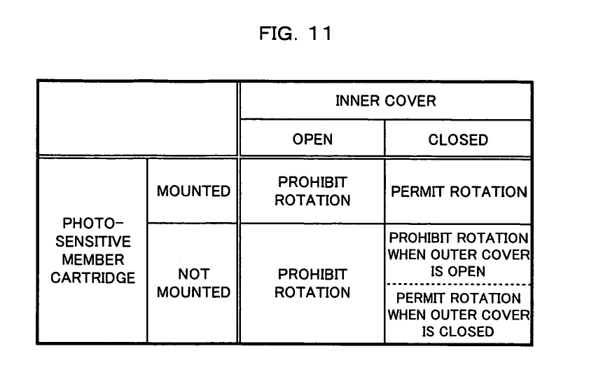

FIG. 10 is a flow chart showing a process of judging whether or not to permit the rotation, and FIG. 11 is a table showing judgment results by the flow of FIG. 10. The CPU 101 first detects the voltage level of the port P1, thereby discriminating the states of the inner cover 110 and the photosensitive member cartridge 2 (Step S101). Here, if the port P1 is at L-level, i.e. the inner cover 110 is closed and the photosensitive member cartridge 2 is mounted as defined in (2) above, this flow proceeds to Step S102, in which the state of the outer cover 100 is discriminated based on the voltage level of the port P2.

Here, if the port P2 is at L-level, i.e. the outer cover 100 is closed as defined in the above (4), the photosensitive member cartridge 2 is mounted and both inner and outer covers 110, 100 are closed. Thus, an ordinary image forming operation can be performed if at least one developer is mounted. Accordingly, the execution of the image forming operation is permitted (Step S103) and, as a matter of course, the rotation of the developing unit 4 is permitted (Step S104). If the port P2 is at H-level, i.e. the outer cover 100 is open as defined in (3) above in Step S102, the image forming operation is not permitted since Step S103 is skipped, but the rotation of the developing unit 4 is permitted (Step S104).

On the other hand, if the port P1 is at H-level, i.e. the inner cover 110 is open or the photosensitive member cartridge is not mounted as defined in (1) above in Step S101, this flow proceeds to Step S105, in which the state of the outer cover 100 is discriminated based on the voltage level of the port P2. The rotation of the developing unit 4 is permitted (Step S104) if the outer cover 100 is closed while being prohibited (Step S106) unless otherwise.

As a result, as shown in FIG. 11, the CPU 101 permits the rotation of the developing unit 4 when at least one of the following two conditions (A), (B) is satisfied while prohibiting this rotation when none of them is satisfied.

(A) The inner cover 110 is closed and the photosensitive member cartridge is mounted.

(B) The outer cover 100 is closed.

The above judgment is made, for example, when any of the buttons in the developer operating section 150 (see FIG. 8) is pressed by the user or when the outer cover 100 is closed. When the rotation is permitted, the CPU 101 outputs a control command to a motor driving circuit 46 to position the developing unit 4 to a specified position if necessary. In response to this control command, the motor driving circuit 46 outputs a drive pulse having a specified pulse number to a stepping motor 47 as a “driving means” for rotating the developing unit 4. Thus, the developing unit 4 is rotated to be positioned to the specified position. For example, in the case that the user presses the button 151Y corresponding to the developer 4Y for yellow, the developing unit 4 is so rotated as to be positioned to the detachment position corresponding to the developer 4Y for yellow (see FIG. 7C). In this state, the user can open the inner cover 110 to detach the developer 4Y having appeared in the developer opening 115 and/or to mount a new developer 4Y through the developer opening 115. In the case of successively detaching the developer for another toner color, the developer of a desired toner color appears in the developer opening 115 by closing the inner cover 110 and pressing the developer operating button corresponding to the desired toner color.

When the outer cover 100 is closed, the developing unit 4 is positioned to the home position (see FIG. 7A). On the other hand, if none of the conditions (A), (B) is satisfied, the developing unit 4 is not rotated even if any of the buttons is pressed since the rotation is prohibited. In this embodiment, the conditions (A), (B) correspond to a “third condition” and a “fourth condition” of the invention, respectively.

By taking the above construction, the developer cartridge or the photosensitive member cartridge 2 can be mounted and detached without impairing user operability in this image forming apparatus. Further, the toner may be freed from the developing rollers 44 by rotating the developing unit 4. However, such toner is prevented from scattering to the outside of the apparatus. Specifically, since the rotation of the developing unit 4 is permitted in accordance with the condition (A) when the inner cover 110 is closed and the photosensitive member cartridge 2 is mounted, the developing unit 4 is not rotated with the developer opening 115 or the photosensitive member opening 165 exposed, with the result that the leak of the toner through these openings can be prevented. Further, as long as the condition (A) holds, the rotation of the developing unit 4 is permitted even with the outer cover 100 open. Thus, the user can successively detach and mount a plurality of developers with good operability without needing to open and close the outer cover 100 every time.

The condition (B) provides a case where the rotation of the developing unit 4 is permitted even if the condition (A) does not hold. This is because, if the outer cover 100 is closed, the toner does not leak to the outside of the apparatus in this state. This also makes it easier to respond to an occurrence of an abnormality such as a power failure and a technical trouble. Specifically, the developing unit 4 may exceptionally stop at or near the developing position (see FIG. 7B) due to a shutoff of power to the apparatus during the image forming operation or a technical trouble. In such a case, none of the developers can be detached, but the photosensitive member cartridge 2 can be detached. In the case that the photosensitive member cartridge 2 is detached in this state, the developing unit 4 cannot be rotated unless a new photosensitive member cartridge 2 is mounted if there is only the condition (A). However, it is not very preferable to mount the photosensitive member cartridge 2 with the developing unit 4 located at or near the developing position since it may damage the apparatus. This problem can be solved by permitting the rotation of the developing unit 4 if the outer cover 100 is closed, even if the photosensitive member cartridge 2 is not mounted.

It should be noted that the mounting/detaching sequence of the developer cartridge and the photosensitive member cartridge 2 is also applicable to the apparatus of the first preferred embodiment.

In the second preferred embodiment, in order to properly administer the lives of the respective developers, the contents of information in the memories provided in the respective developers and the information on the developers saved in the apparatus main body need to agree with each other when the developer is detached and mounted. Thus, an actual movement of the developing unit 4 and the mounting/detaching sequence when the user operates the developer operating section 150 are as follows.

For example, if the user presses the operating button corresponding to the developer 4C for cyan, the developing unit 4 is rotated to be first located at the position shown in FIG. 7B (developing position for yellow). At this position, the connector 49C provided in the cyan developer 4C and the main-body side connector 109 face each other. The two connectors 49C, 109 are connected with each other by moving the main-body side connector 109 to the developer-side connector 49C in this state. As a result, the developer information on the developer 4C is written in the memory 92 (see FIG. 5) provided in the developer 4C.

Upon the completion of the writing, the main-body side connector 109 is separated from the developer-side connector 49C and then the developing unit 4 is rotated to the detachment position for the developer 49C. Thus, the user can open the cover and detach the developer 4C.

On the other hand, when the cover is closed, the developing unit 4 is rotated to the position shown in FIG. 7B. Similar to the detachment, a communication is attempted between the memory provided in the developer and the CPU 101. This enables a judgment as to whether or not the developer has been mounted and, when a new developer is mounted, enables the developer information on the developer to be read from the memory and used as the administrative information. Thereafter, the developing unit 4 is moved to the home position shown in FIG. 7A. The other developers can be detached and mounted in a similar manner.

As described above, since the developer can be detached and mounted only under the control of the engine controller 10 in this embodiment, the developer information can be properly exchanged between the apparatus main body and the developer.

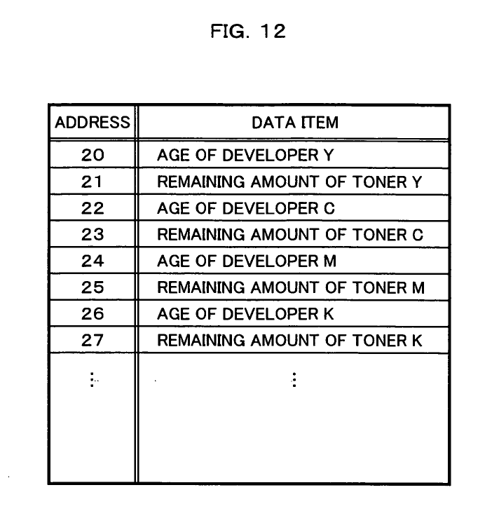

FIG. 12 is a diagram showing the developer information saved in the FRAM. In this embodiment, in addition to the pieces of information (see FIG. 3) on the used states of the respective units of the apparatus used as the administrative information in the first embodiment, information on the used states of the respective four developers 4Y, 4C, 4M, 4K (developer information) is saved in the FRAM 108 as a part of the administrative information. As shown in FIG. 12, the developer information used here includes the ages of the respective developers, i.e. cumulative values of hours the respective developers have been used up to the present for the image formation, the remaining amounts of toner in the respective developers, i.e. values obtained by subtracting amounts of toner consumed up to the present from amounts of toner initially contained in the respective developers. However, the developer information is not limited to the above.

These values are read from the memories when the developers are mounted into the apparatus main body and written in the FRAM 108 as the administrative information. These values are updated upon occasion as the apparatus is used and, when the user detaches the developer, these pieces of information are written in the memory in the developer prior to the detachment.

As described above, in this embodiment, the developers 4Y, 4C, 4M, 4K detachable from the apparatus main body are provided with the nonvolatile memories 91 through 94 for saving the developer information on the used states of the corresponding developers. In the apparatus main body, the life of the apparatus is administered by the CPU 101 based on the pieces of information saved in these memories. Upon detaching the developer, the developer information is written in the memory within the developer prior to the detachment.

Thus, the lives of the developers can be properly administered in the apparatus main body in the apparatus of this embodiment. Further, since the information on the used state of the developer is also saved in the memory of this developer, the life of the developer can be administered while maintaining continuity even if the developer is the one detached from the apparatus or the one used in another apparatus. Since the information is administered in the apparatus main body same as in the apparatus of the first embodiment, a problem of losing the developer information due to a technical trouble or the like, making it unable to administer the lives of the developers, can be prevented.

(Modifications)

The invention is not limited to the embodiments described above and various changes other than those described above can be made without departing from the scope and spirit of the invention. For example, although the exchange flag is checked every time the updating process of FIG. 4 is executed in the foregoing embodiments, the exchange flag may be checked only in the updating process executed immediately after the apparatus is turned on and such a check may be left out in other cases since parts are normally exchanged with the power shut off.

The pieces of information to be saved as the “administrative information” are not limited to those described above and various other pieces of information can be thought as such. For example, the ages of the respective units when a service person cleans and inspects the respective units of the apparatus may be saved and the lives may be administered based on the working hours from such an operation to the present. Besides these values, parameters which are not set by the control of the apparatus itself and desired to be saved even after the engine controller 10 or the like is exchanged such as the mechanical properties of the engine EG and various set values customized according to the user's preferences are desirably saved in the FRAM 108 as the administrative information and in the EEPROM 117 as the auxiliary information.

Further, in the foregoing embodiments, the EEPROM 117 provided for the operation of the CPU 111 of the main controller 11 has a function as the “auxiliary storage means” of the invention. Accordingly, the EEPROM 117 is accessed via the CPU 111 from the CPU 101 of the engine controller 10 instead of being directly accessed. However, a special memory as the “auxiliary storage means” may be, of course, separately provided. In such a case, the CPU 101 can singly function as the “administering means” since the CPU 101 of the engine controller 10 can directly access this special memory.

The position where the memory as the “auxiliary storage means” is provided is not limited to the one on the main controller 11 as in the foregoing embodiments, and it may be any arbitrary position such as the one on an other detachable unit, circuit board module or motherboard fixed to the apparatus main body. However, in an apparatus in which parts are supposed to be exchanged by the circuit board module or unit by unit, the “main storage means” and the “auxiliary storage means” are desirably mounted on separate modules or separate units since the administrative information is lost if they are detached together.

The content of the information saved as the “discrimination information” in the exchange storage unit is not limited to the flag format and may take any desired format. For example, different serial numbers may be designated to the units and a judgment as to whether or not the storage units are same may be made in the apparatus main body by comparing the read serial numbers.

Although the FRAM 108 is the “storage unit” detachable from the apparatus main body by means of the socket in the foregoing embodiments, a function block including a storage device such as an FRAM may be constructed to be detachable. In such a case, this function block corresponds to the “storage unit” and a function block separately prepared for exchange corresponds to the “exchange storage unit”.

Further, in the second embodiment, the inner cover 110 free to open and close is provided for the developer opening 115 used to detach and mount the developers and the outer cover 100 is provided to cover the developer opening 115 and the photosensitive member opening 165. However, the invention is applicable, for example, to an image forming apparatus having a different construction as described below.

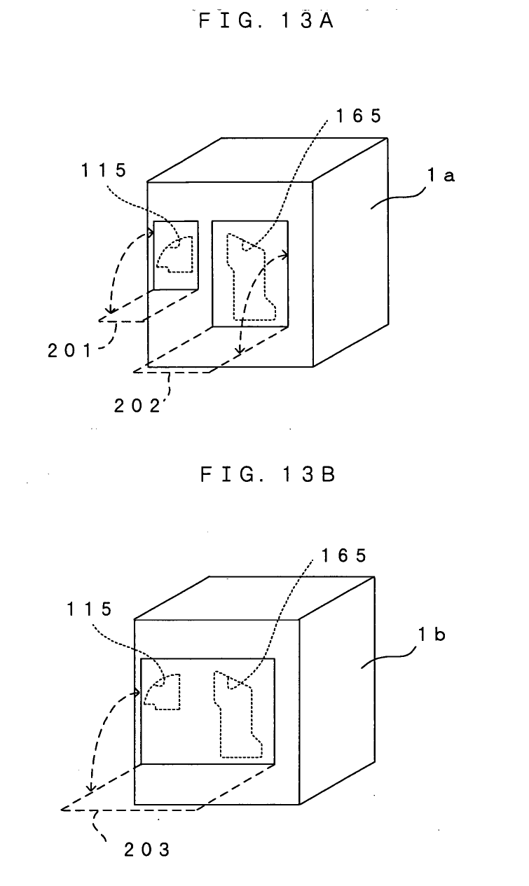

FIGS. 13A and 13B are diagrams showing modifications of the image forming apparatus according to the invention. In an apparatus 1a of FIG. 13A, a developer cover 201 for covering the developer opening 115 and a photosensitive member cover 202 for covering the photosensitive member opening 165 are both so formed as to be opened and closed from the outside of the apparatus. The inner cover 110 cannot be opened unless the outer cover 100 is opened in the foregoing embodiment, whereas the two covers can be independently opened and closed in this example. In such an apparatus 1a, toner can be prevented from scattering to the outside of the apparatus by permitting the rotation of the developing unit when at least one of the following two conditions (C), (D) holds:

(C) The photosensitive member cartridge 2 is mounted.

(D) The photosensitive member cover 202 is closed.

In addition, if whether or not the developer cover 201 is closed is discriminated and the rotation of the developing unit is prohibited when the developer cover 201 is open, the toner can be more effectively prevented from scattering. It should be appreciated that these covers 201, 202 are not necessarily essential elements of the present invention. Even in the case that these covers are not provided, the toner can be prevented from scattering during the rotation of the developing unit if the rotation of the developing unit is not permitted so long as the photosensitive member cartridge 2 is not mounted.

Further, in an apparatus 1b of FIG. 13B, an outer cover 203 is formed to cover both the developer opening 115 and the photosensitive member opening 165 and no cover corresponding to the inner cover 110 of the foregoing embodiment is provided. In the apparatus 1b thus constructed, toner can be prevented from scattering to the outside of the apparatus by permitting the rotation of the developing unit when at least one of the following two conditions (E), (F) holds:

(E) The photosensitive member cartridge 2 is mounted.

(F) The outer cover 203 is closed.

Out of the above conditions, the conditions (C) and (E) correspond to the “first condition” of the present invention. The conditions (D) and (F) correspond to the “second condition”.

Further, in the second preferred embodiment, the number of the ports of the CPU 101 is reduced by connecting the limit switch 132 for detecting the open and closed states of the inner cover 110 and the limit switch 133 for detecting the mounted state of the photosensitive member cartridge 2 in series. However, the signals from these switches may be, of course, individually inputted to the CPU 101.

Further, in the second preferred embodiment, the CPU 101 gives suitable control commands to the motor driving circuit 46 in accordance with the signals from the respective limit switches to permit and prohibit the rotation of the developing unit 4. Alternatively, for example, a switch may be provided in a power supply line of the motor driving circuit 46 or in a power supplying line from the motor driving circuit 46 to the stepping motor 47 and may be turned off to shut off the supply of the power to the motor 47 upon prohibiting the rotation of the developing unit 4. In this case, the power supplying line may be directly opened and closed by turning the switch on and off as the cover is opened and closed or depending on the absence or presence of the photosensitive member cartridge. This switch functions as the “control means” of the invention in such a case.

Although “the image forming operation is possible if at least one developer is mounted” in the foregoing embodiments, the invention is not limited thereto and the image forming operation may be possible when all the developers are mounted. The invention is applicable to apparatuses including at least a developing rotary and constructed such that the developing rotary can be rotated even if all the developer cartridges are not necessarily mounted for the mounting and detaching operation of the developer at the time of exchanging the developers.

The foregoing embodiments concern the apparatuses provided with the rotary developing unit in which the four developers corresponding to four colors of yellow, cyan, magenta and black are mountable and with the reversing conveyance path FR for the image formation on both surfaces of the sheet S. The invention is not limited to such apparatuses and is applicable, for example, to apparatuses provided with a developing rotary in which a different number of developer cartridges are mountable and/or adapted to form an image only on one surface of each sheet S. For instance, the invention is applicable to an apparatus capable of forming only monochromatic images in black. Instead of being applied to the rotary developing type apparatuses as in the foregoing embodiments, the invention can be applied to image forming apparatuses of so-called tandem type in which developers corresponding to the respective toner colors are arranged in a row along a sheet conveying direction. Further, the invention is applicable not only to apparatuses of the electrophotographic type as in the foregoing embodiments, but also to image forming apparatuses in general.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. An image forming apparatus, comprising:
administering means for administering the life of the apparatus in accordance with administrative information on the used state of the apparatus;
main storage means for renewably saving the administrative information; and
auxiliary storage means for saving the administrative information as auxiliary information,
wherein the administering means reads pieces of information saved in the main storage means and the auxiliary storage means if necessary and updates contents of the information in the main storage means and the auxiliary storage means in accordance with the reading result.

2. An image forming apparatus according to claim 1, wherein:
the administrative information and the auxiliary information include index information representing a working amount of the apparatus from a specified reference point of time, and
the administering means saves the administrative information read from the main storage means in the auxiliary storage means as the auxiliary information if the working amount of the apparatus grasped from the index information read from the main storage means is larger than the working amount of the apparatus grasped from the index information read from the auxiliary storage means.

3. An image forming apparatus according to claim 1, wherein:
the main storage means is detachable from the apparatus and exchangeable for another main storage means for exchange in which specified identification information is saved beforehand, and
the administering means saves the auxiliary information read from the auxiliary storage means in the main storage means and deletes the identification information saved in the main storage means when the information read from the main storage means mounted in the apparatus includes the identification information.

4. An image forming apparatus according to claim 1, further comprising at least one detachable unit detachably mountable into a main body of the apparatus, wherein the administrative information saved in the main storage means includes information on the used state of at least one detachable unit.

5. An image forming apparatus according to claim 4, wherein at least one developer for containing a developing agent for image formation is mountably constructed as the detachable unit, and the administrative information and the auxiliary information include developer information on the used state of the developer.

6. An image forming apparatus according to claim 5, wherein:
the developer includes a developer information storage means for saving the developer information, and
when the developer is to be detached from the main body of the apparatus,
the administering means writes the developer information read from the developer information storage means in the main storage means as at least a part of the administrative information when the developer is mounted into the main body of the apparatus while writing information corresponding to the developer information out of the administrative information saved in the main storage means in the developer information storage means prior to the detachment of the developer from the main body of the apparatus.

7. An image forming apparatus according to claim 4, wherein the main storage means is provided in one detachable unit and the auxiliary storage means is provided in the detachable unit other than the one in which the main storage means is provided or in the main body of the apparatus.

8. An image forming apparatus according to claim 1, further comprising a notifying means for notifying an occurrence of an abnormality when the abnormality occurs in an access from the administering means to the main storage means.

9. An information administering method for administering the life of an image forming apparatus in accordance with administrative information on the used state of the image forming apparatus, comprising the steps of:
writing the administrative information in main storage means;
writing the administrative information in auxiliary storage means as auxiliary information if necessary;
reading the pieces of information saved in the main storage means and the auxiliary storage means; and
updating contents of the information saved in the main storage means or the auxiliary storage means based on the reading results from the main storage means and the auxiliary storage means.

10. An image forming apparatus, comprising:
main storage means detachably mountable into a main body of the apparatus and adapted to save administrative information on the used state of the apparatus; and
administering means for reading/writing the administrative information from/in the main storage means mounted in the apparatus and administering the life of the apparatus in accordance with the administrative information saved in the main storage means,
wherein the administering means judges whether or not the information read from the main storage means mounted in the apparatus includes identification information representing a difference between this main storage means and the main storage means in which the information was written prior to the readout, and controls the reading/writing of the administrative information from/in the main storage means based on a judgment result.

11. An image forming apparatus according to claim 10, further comprising auxiliary storage means for auxiliary saving the administrative information if necessary, wherein the administering means writes the information read from the auxiliary storage means in the main storage means and deletes the identification information saved in the main storage means when the information read from the main storage means includes the identification information.

12. An image forming apparatus according to claim 10, further comprising at least one detachable unit detachably mountable into the main body of the apparatus, wherein the administrative information saved in the main storage means includes information on the used state of at least one detachable unit.

13. An image forming apparatus according to claim 11, further comprising at least one detachable unit detachably mountable into a main body of the apparatus, wherein either one of the main storage means and the auxiliary storage means is provided in one detachable unit and the other thereof is provided in the detachable unit other than the one in which the one detachable unit or in the main body of the apparatus.

14. An exchange storage unit replaceable for a storage unit mountable into an image forming apparatus for saving administrative information on the used state of the apparatus, wherein identification information for distinguishing the exchange storage unit and the storage unit mounted in the apparatus from each other is saved beforehand.

15. An information administering method for an image forming apparatus in which a main storage means for saving administrative information on the used state of the apparatus is detachably mountable and the life of the apparatus is administered in accordance with the administrative information, comprising the steps of:
reading/writing the administrative information from/in the main storage means mounted in the apparatus if necessary;
judging whether or not the information read from the main storage means mounted in the apparatus includes identification information representing a difference between this main storage means and the main storage means in which the information was written prior to the readout; and
controlling the reading/writing of the administrative information from/in the main storage means based on a judgment result.

16. An information administering method according to claim 15, further comprising the steps of:
saving the administrative information in an auxiliary storage means if necessary; and
writing the information read from the auxiliary storage means in the main storage means as the administrative information and deleting the identification information saved in the main storage means when the identification information is judged to be included in the judging step.

17. An image forming apparatus, comprising:
a photosensitive member cartridge detachably mountable into a main body of the apparatus through a photosensitive member opening formed in the main body of the apparatus;
a developing rotary which is rotatably constructed about a center axis thereof with respect to the main body of the apparatus and in which at least one developer cartridge is mountable;
driving means for rotating the developing rotary to position the developing rotary to a specified detachment position where the developing cartridge can be mounted and detached through a developer opening formed in the main body of the apparatus; and
control means for prohibiting the rotation of the developing rotary by the driving means when the photosensitive member cartridge is not mounted in the main body of the apparatus.

18. An image forming apparatus according to claim 17, further comprising a developer covering member free to open and close the developer opening.

19. An image forming apparatus according to claim 18, wherein the control means prohibits the rotation of the developing rotary by the driving means when the developer covering means is open.

20. An image forming apparatus according to claim 17, further comprising a photosensitive member covering member openably and closably mounted on the main body of the apparatus and adapted to cover at least the photosensitive member opening in a closed state thereof,
wherein the control means permits the rotation of the developing rotary by the driving means regardless of whether the photosensitive member cartridge is mounted or not when the photosensitive member covering member is closed.

21. An image forming apparatus according to claim 20, wherein the photosensitive member covering member covers both the developer opening and the photosensitive member opening in a closed state thereof.

22. An image forming apparatus, comprising:
a photosensitive member cartridge detachably mountable into a main body of the apparatus through a photosensitive member opening formed in the main body of the apparatus;
a developing rotary which is rotatably constructed about a center axis thereof with respect to the main body of the apparatus and in which at least one developer cartridge is mountable;
driving means for rotating the developing rotary to position the developing rotary to a specified detachment position where the developing cartridge can be mounted and detached;
a photosensitive member covering member openably and closably mounted on the main body of the apparatus and adapted to cover at least the photosensitive member opening in a closed state thereof; and
control means for permitting the rotation of the developing rotary by the driving means when at least one of a first and a second conditions is satisfied while prohibiting the rotation of the developing rotary by the driving means when none of the first and second conditions is satisfied, the first condition being the condition that the photosensitive member cartridge is mounted in the main body of the apparatus, the second condition being the condition that the photosensitive member covering member is closed.

23. An image forming apparatus, comprising:
a photosensitive member cartridge detachably mountable into a main body of the apparatus through a photosensitive member opening formed in the main body of the apparatus;
a developing rotary which is rotatably constructed about a center axis thereof with respect to the main body of the apparatus and in which at least one developer cartridge is mountable;
driving means for rotating the developing rotary to position the developing rotary to a specified detachment position where the developing cartridge can be mounted and detached through a developer opening formed in the main body of the apparatus;
a photosensitive member covering member openably and closably mounted on the main body of the apparatus and adapted to cover at least the photosensitive member opening in a closed state thereof;
a developer covering member free to open and close the developer opening; and
control means for permitting the rotation of the developing rotary by the driving means when at least one of a third and a fourth conditions is satisfied while prohibiting the rotation of the developing rotary by the driving means when none of the third and fourth conditions is satisfied, the third condition being the condition that the photosensitive member cartridge is mounted in the main body of the apparatus and the developer covering member is closed, the fourth condition being the condition that the photosensitive member covering member is closed.

24. An image forming apparatus according to claim 23, wherein the photosensitive member covering member covers both the developer opening and the photosensitive member opening in the closed state thereof.
